(19) United States
(12) Patent Application Publication
(10) Pub. No.: US 2025/0392328 A1
(43) Pub. Date: Dec. 25, 2025

(54) FAST AUTOMATIC GAIN CONTROL IN A WIRELESS RECEIVER

(71) Applicant: QUALCOMM Incorporated, San Diego, CA (US)

(72) Inventors: Meenakshisundaram GURUNATHAN, Hyderabad (IN); Soumen CHAKRABORTY, Bangalore (IN); Krishnaswamy THIAGARAJAN, Bangalore (IN); Arul Durai Murugan PALANIVELU, Bangalore (IN); James GARDNER, San Ramon, CA (US); Didier Johannes Richard VAN NEE, Tull en 't Waal (NL); Manav LNU, Hyderabad (IN); Rakesh JALOTA, Hyderabad (IN); Anurag TIWARI, Bangalore (IN); Balasubramanian RAMACHANDRAN, Hyderabad (IN)

(21) Appl. No.: 18/749,950

(22) Filed: Jun. 21, 2024

(51) Int. Cl. H04B 1/00; H03F 3/24; H03G 3/30; H04B 1/10; H04B 1/18

(52) U.S. Cl. CPC H04B 1/0053; H03F 3/245; H03G 3/3036; H04B 1/109; H04B 1/18; H03F 2200/294; H03F 2200/451; H03G 2201/103

(57) ABSTRACT

Methods and apparatus for performing automatic gain control in wireless receiver front-end circuitry are described. An example apparatus includes a receiver and control logic coupled to the receiver. The receiver generally includes a receive path including a first amplifier, a second amplifier having an output coupled to an input of the first amplifier, a mixer having an output coupled to an input of the second amplifier, and a third amplifier having an output coupled to an input of the mixer. The receiver also includes a first saturation detector circuit, a second saturation detector circuit, and a third saturation detector circuit. The control logic is configured to control a gain state of the third amplifier, based on one or more respective signals output from at least one of the first saturation detector circuit, the second saturation detector circuit, or the third saturation detector circuit.

### TECHNICAL FIELD

Certain aspects of the present disclosure generally relate to electronic circuits and, more particularly, to techniques and apparatus for performing automatic gain control (AGC) in wireless receiver front-end circuitry.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include radio frequency front-end (RFFE) circuitry, which may be used for processing and amplifying signals for transmission and reception, for example.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include improved receive (RX) automatic gain control (AGC) performance, such as reduced RX AGC settling time, as an illustrative example.

Certain aspects of the present disclosure provide an apparatus for wireless communications. The apparatus generally includes a receiver and control logic coupled to the receiver. The receiver includes: a receive path including a first amplifier, a second amplifier having an output coupled to an input of the first amplifier, a mixer having an output coupled to an input of the second amplifier, and a third amplifier having an output coupled to an input of the mixer; a first saturation detector circuit coupled to at least one output of the first amplifier and configured to generate a first signal to indicate saturation within the receiver when an output signal from the first amplifier satisfies a first criterion; a second saturation detector circuit coupled to at least one output of the second amplifier and configured to generate a second signal to indicate saturation within the receiver when an output signal from the second amplifier satisfies a second criterion; and a third saturation detector circuit coupled to at least one output of the third amplifier and configured to generate a third signal to indicate saturation within the receiver when an output signal from the third amplifier satisfies a third criterion. The control logic is configured to control a gain state of the third amplifier, based on at least one of the first signal, the second signal, or the third signal.

Certain aspects of the present disclosure provide a wireless device. The wireless device includes an antenna, a receiver coupled to the antenna, and control logic coupled to the receiver. The receiver includes: a receive path comprising a first amplifier, a second amplifier having an output coupled to an input of the first amplifier, a mixer having an output coupled to an input of the second amplifier, and a third amplifier having an output coupled to an input of the mixer; a first saturation detector circuit coupled to at least one output of the first amplifier and configured to generate a first signal to indicate saturation within the receiver when an output signal from the first amplifier satisfies a first criterion; a second saturation detector circuit coupled to at least one output of the second amplifier and configured to generate a second signal to indicate saturation within the receiver when an output signal from the second amplifier satisfies a second criterion; and a third saturation detector circuit coupled to at least one output of the third amplifier and configured to generate a third signal to indicate saturation within the receiver when an output signal from the third amplifier satisfies a third criterion. The control logic is configured to control a gain state of the third amplifier, based on at least one of the first signal, the second signal, or the third signal.

Certain aspects of the present disclosure provide a method for wireless communications. The method generally includes generating a first signal to indicate saturation within a receiver when an output signal from a first amplifier in a receive path of the receiver satisfies a first criterion. The method also includes generating a second signal to indicate saturation within the receiver when an output signal from a second amplifier in the receive path satisfies a second criterion, the second amplifier having an output coupled to an input of the first amplifier and having an input coupled to an output of a mixer in the receive path. The method also includes generating a third signal to indicate saturation within the receiver when an output signal from a third amplifier in the receive path satisfies a third criterion, the third amplifier having an output coupled to an input of the mixer. The method further includes controlling a gain state of the third amplifier, based on at least one of the first signal, the second signal, or the third signal.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example a base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 illustrates an example apparatus for performing receiver automatic gain control for a wireless receive path, in accordance with certain aspects of the present disclosure.

FIG. 5 illustrates an example saturation detector circuit, in accordance with certain aspects of the present disclosure.

FIG. 6 illustrates an example observation window, in accordance with certain aspects of the present disclosure.

FIG. 7 is a flowchart of an example method for performing receiver automatic gain control for a receive path, in accordance with certain aspects of the present disclosure.

FIG. 8 is a flow diagram of example operations for performing receiver automatic gain control for a receive path, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to techniques and apparatus for performing fast automatic gain control (AGC) for wireless receiver front-end circuitry.

A wireless device may be capable of communicating via multiple radio access technologies (RATs), such as wireless wide area network (WWAN) RATs (e.g., 5G New Radio (NR), Evolved Universal Terrestrial Radio Access (E-UTRA), Universal Mobile Telecommunications System (UMTS) and/or code division multiple access (CDMA)) and wireless local area network (WLAN) RATs (e.g., Institute of Electrical and Electronics Engineers (IEEE) 802.11), as illustrative, non-limiting examples. In cases where a wireless device supports multiple RATs, certain wireless devices (e.g., internet of things (IoT) devices) may use a common radio frequency (RF) front end (RFFE) for multiple RATs (e.g., WWAN and WLAN RATs).

One potential drawback to using a common RFFE for multiple RATs is that it may be difficult to use a common receiver automatic gain control (RxAGC) logic across multiple RATs in cases where the RxAGC logic has to settle within different timing targets. For example, depending on the distance between an access point (AP) and a user equipment (UE), the UE may receive signals (e.g., beacons) at different power levels from the AP. As the signal strength at an antenna port of the UE could vary significantly due to fading, for example, a low noise amplifier (LNA) gain of the UE may be adjusted accordingly by the RxAGC logic of the UE, in order to ensure that the signal is well within the dynamic range of an analog-to-digital converter (ADC) of the UE to avoid saturating the ADC (as well as other components/circuitry within the receiver of the UE).

With multiple RATs, however, the RxAGC logic may have to settle within different timing targets. For example, for WLAN RATs, the settling target may be on the order of a few microseconds, whereas, for WWAN RATs, the settling target may be on the order of hundreds of microseconds. For instance, for WLAN RATs, the RxAGC logic may have to settle within approximately 4 microseconds (μs), so that the UE can perform phase estimation followed by automatic gain control within the duration of a short training field (STF) of a received signal (e.g., beacon) (e.g., approximately 8 μs). On the other hand, for WWAN RATs, the RxAGC logic may settle within 500 μs. Due to the different settling targets, implementing the WWAN-based RxAGC logic for WLAN scenarios, may be infeasible, impacting the wireless performance of the UE in terms of reduced throughput, increased latency, and lower transmission range, as illustrative, non-limiting examples. For example, WAN-based receivers may use wideband energy estimation (WBEE) and narrowband energy estimation (NBEE) to determine the LNA gain state during RxAGC; however, using WBEE and NBEE for WLAN-based receivers may be time-consuming due in part to software overheads and in-phase (I) sample and quadrature (Q) sample collection duration.

To address this, certain aspects described herein provide an improved RxAGC algorithm (or RxAGC logic) for controlling the gain of one or more amplifiers within the receive (RX) chain of a wireless device. The RxAGC algorithm described herein may be used for receivers that support multiple different RATs, such as WWAN RATs and WLAN RATs, as illustrative examples. For example, the RxAGC algorithm described herein may have an improved (e.g., lower) settling time relative to conventional RxAGC algorithms, allowing the RxAGC algorithm to meet the settling targets associated with WAN and WLAN, for example. Accordingly, by using the RxAGC algorithm described herein, the performance of wireless receives (relative to conventional RxAGC algorithms) may be significantly improved in terms of higher throughput, reduced latency, and higher transmission range, as illustrative, non-limiting examples.

Note that, as used herein, the term “wireless receiver” may refer to the RX operations of a wireless transceiver, RX chain of a wireless transceiver, or RX path of a wireless transceiver. Accordingly, the terms “wireless receiver,” “RX operations of a wireless transceiver,” “RX path of a wireless transceiver,” and “RX chain of a wireless transceiver” may be used interchangeably.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

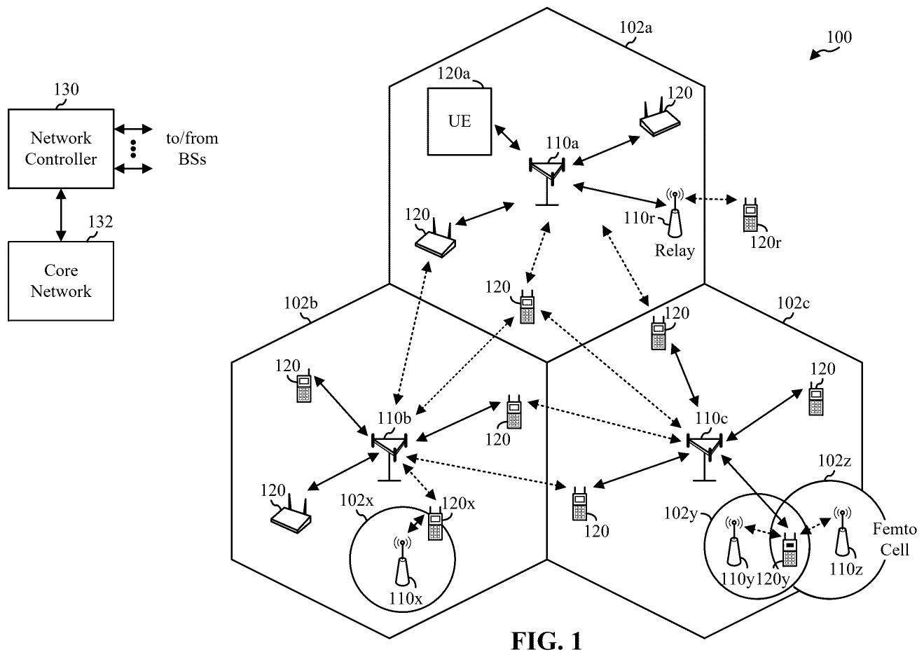

FIG. 1 illustrates an example wireless communications network 100, in which aspects of the present disclosure may be practiced. For example, the wireless communications network 100 may be a New Radio (NR) system (e.g., a Fifth Generation (5G) NR network), a Sixth Generation (6G) cellular system, an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a transceiver front end (TX/RX) (also known as a radio frequency front end (RFFE)). The RFFE may implement RxAGC using one or more techniques described herein.

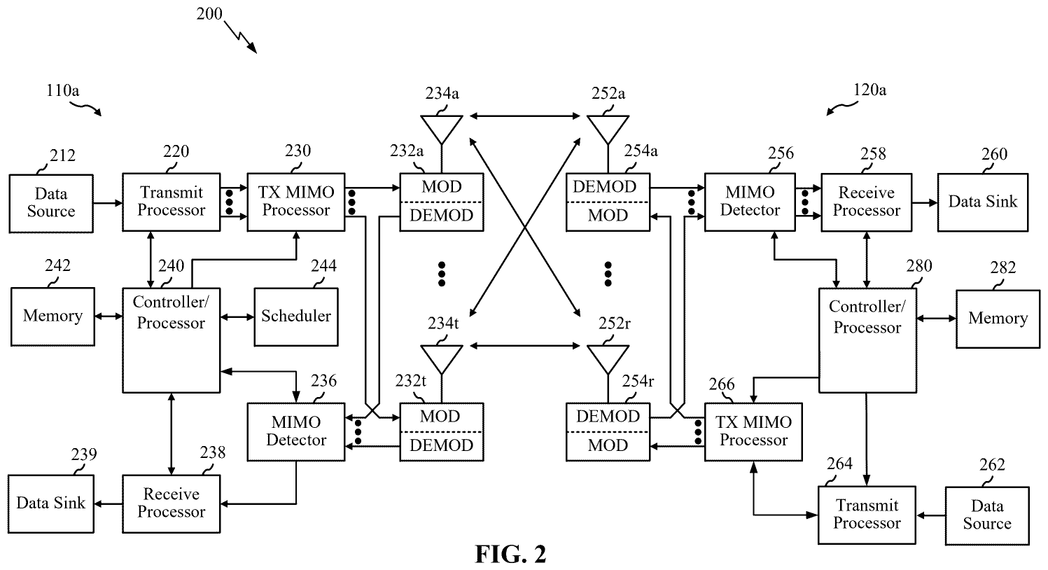

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH, demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232 and/or the transceivers 254 may include RF front-end circuitry that implements RxAGC using one or more techniques described herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

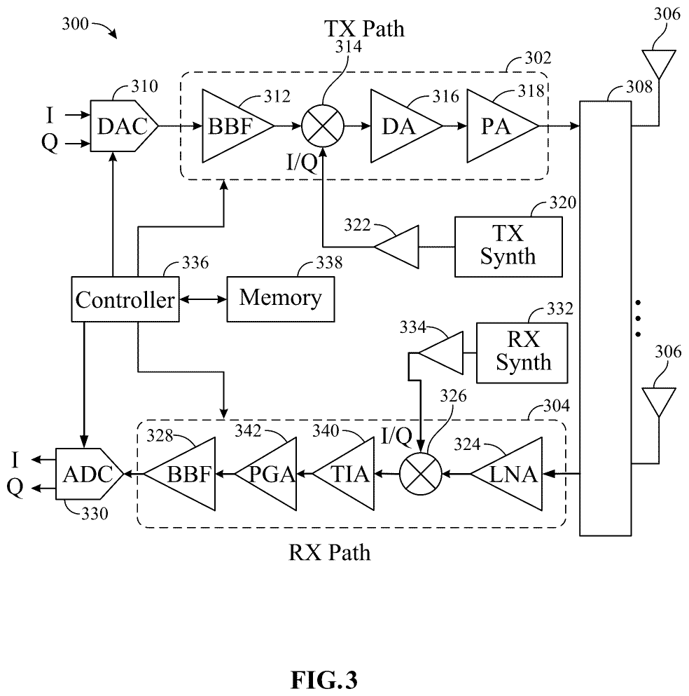

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit (TX) chain” or “transmit (TX) operations”) for transmitting signals via one or more antennas 306 and at least one receive (RX) path 304 (also known as a “receive (RX) chain” or “receive (RX) operations”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC. In such aspects, the RFIC (and thus the DA 316) may be coupled to the PA 318 over one or more interconnections, for example, a conductive line or cabling such as a coaxial cable or flex circuit.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, a transimpedance amplifier (TIA) 340, a programmable gain amplifier (PGA) 342, and a baseband filter (BBF) 328. The LNA 324, the mixer 326, the TIA 340, the PGA 342, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals (e.g., current signals) output by the mixer 326 may be converted into baseband voltage signals by the TIA 340, and the baseband voltage signals output by the TIA 340 may be amplified by the PGA 342. The amplified baseband voltage signals output by the PGA 342 may be filtered by the BBF 328 before being converted by an analog-to-digital converter (ADC) 330 to digital I and/or Q signals for digital signal processing. In certain aspects, the PGA 342 may be a programmable baseband amplifier (PBA).

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for automatic gain control in any of various other suitable systems (e.g., an audio system or other electronic system).

### Example Fast Automatic Gain Control for a Wireless Receiver

As noted, certain wireless devices (e.g., IoT devices) may use a common RFFE (e.g., RF transceiver circuit 300) for multiple RATs, such as WWAN RATs and WLAN RATs, as illustrative examples. In such wireless devices, aspects described herein provide a “fast” RxAGC algorithm that can achieve a lower settling time relative to conventional RxAGC algorithms. In certain aspects, the “fast” RxAGC algorithm described herein may significantly improve (e.g., decrease) the RxAGC settling time by detecting the incoming receive signal strength indicator (RSSI) using multiple saturation detectors employed at different portions of the RX path, and performing a coarse gain correction through an LNA gain state change in one step, as opposed to multiple steps. That is, as opposed to using a two-step RxAGC algorithm that involves coarse gain correction in the analog front-end followed by fine gain correction in the digital front-end, the “fast” RxAGC algorithm described herein may make use of a high ADC dynamic range and perform one-step coarse gain correction using multiple saturation detectors. Performing one-step coarse gain correction may avoid the software overhead generally associated with performing fine gain estimation in the digital front-end.

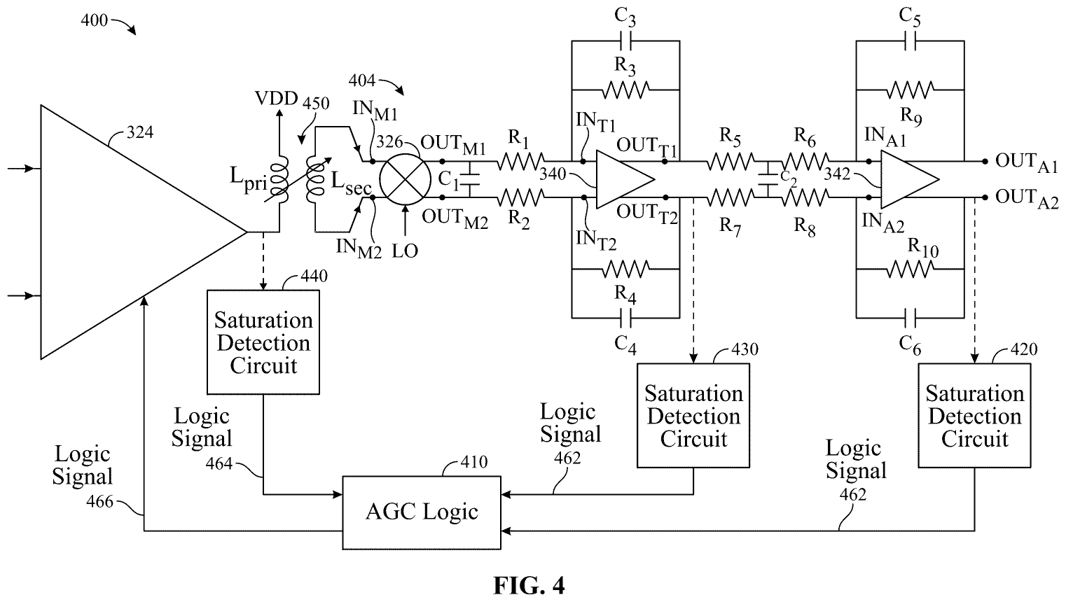

FIG. 4 illustrates an example apparatus 400 for performing RxAGC for a wireless RX path 404, according to certain aspects of the present disclosure. Here, the RX path 404 may be one example implementation of the RX path 304 illustrated in FIG. 3. As shown, the RX path 404 includes, without limitation, an LNA 324, a transformer 450, a mixer 326, a TIA 340, a PGA 342, capacitive elements C₁ to C₆, and resistive elements R₁ to R₁₀. In certain aspects, the transformer 450 is a tunable transformer.

The LNA 324 may provide a single-ended output to the transformer 450, and the transformer 450 may be configured to convert the single-ended output from the LNA 324 into a dual-ended signal, which is provided to first and second inputs (IN_{M1} and IN_{M2}) of the mixer 326. As shown, the transformer 450 includes a primary winding (Lₚᵣᵢ) having a first terminal coupled to the output of the LNA 324 and a second terminal coupled to a voltage supply node (VDD). The transformer 450 also includes a secondary winding (L_{sec}) having first and second terminals coupled to first and second inputs (IN_{M1} and IN_{M2}) of the mixer 326, respectively.

The mixer 326 includes first and second outputs (OUT_{M1} and OUT_{M2}) coupled to first and second inputs (IN_{T1} and IN_{T2}) of the TIA 340, respectively. As shown, the first output (OUT_{M1}) of the mixer 326 may be coupled to the first input (IN_{T1}) of the TIA 340 via resistive element R₁, and the second output (OUT_{M2}) of the mixer 326 may be coupled to the second input (IN_{T2}) of the TIA 340 via resistive element R₂. Capacitive element C₁ may be coupled between the first and second inputs (IN_{T1} and IN_{T2}) of the TIA 340.

The TIA 340 includes first and second outputs (OUT_{T1} and OUT_{T2}) coupled to first and second inputs (IN_{A1} and IN_{A2}) of the PGA 342, respectively. As shown, the first output (OUT_{T1}) of the TIA 340 may be coupled to the first input (IN_{A1}) of the PGA 342 via resistive elements R₅ and R₆, and the second output (OUT_{T2}) of the TIA 340 may be coupled to the second input (IN_{A2}) of the PGA 342 via resistive elements R₇ and R₈. Capacitive element C₂ may be coupled between the first and second inputs (IN_{A1} and IN_{A2}) of the PGA 342.

An impedance (e.g., capacitive element C₃ and resistive element R₃) may be coupled between the first input (IN_{T1}) and the first output (OUT_{T1}) of the TIA 340, and an impedance (e.g., capacitive element C₄ and resistive element R₄) may be coupled between the second input (IN_{T2}) and second output (OUT_{T2}) of the TIA 340. Similarly, an impedance (e.g., capacitive element C₅ and resistive element R₉) may be coupled between the first input (IN_{A1}) and a first output (OUT_{A1}) of the PGA 342, and an impedance (e.g., capacitive element C₆ and resistive element R₁₀) may be coupled between the second input (IN_{A2}) and a second output (OUT_{A2}) of the PGA 342.

In certain aspects, the apparatus 400 may implement multiple saturation detectors with different thresholds to detect the incoming RSSI and determine whether the receiver is saturated. In the depicted example, the apparatus 400 includes a saturation detector circuit 420 coupled to the second output (OUT_{A2}) of the PGA 342, a saturation detector circuit 430 coupled to the second output (OUT_{T2}) of the TIA 340, and a saturation detector circuit 440 coupled to the output of the LNA 324. Although three saturation detector circuits are depicted in FIG. 3, certain aspects described herein may use more than 3 saturation detector circuits to detect the incoming RSSI and determine whether the receiver is saturated.

Each saturation detector circuit 420, 430, and 440 is generally configured to monitor the power level of one or more reception signals at a respective portion of the RX path 404 over a respective past running time window, and determine, based on the monitoring, whether there is saturation within the RX path 404. For example, the saturation detector circuit 420 may be configured to monitor the power level of an output signal from the PGA 342 over a first past running time window and to generate a logic signal 460 to indicate saturation within the receiver when the output signal from the PGA 342 satisfies a first criterion. Similarly, the saturation detector circuit 430 may be configured to monitor the power level of an output signal from the TIA 340 over a second past running time window and to generate a logic signal 462 to indicate saturation within the receiver when the output signal from the TIA 340 satisfies a second criterion. Similarly, the saturation detector circuit 440 may be configured to monitor the power level of an output signal from the LNA 324 over a third past running time window and to generate a logic signal 464 to indicate saturation within the receiver when the output signal from the LNA 324 satisfies a third criterion. In certain aspects, the saturation detector circuits 420, 430, 440 may operate in parallel (e.g., concurrently).

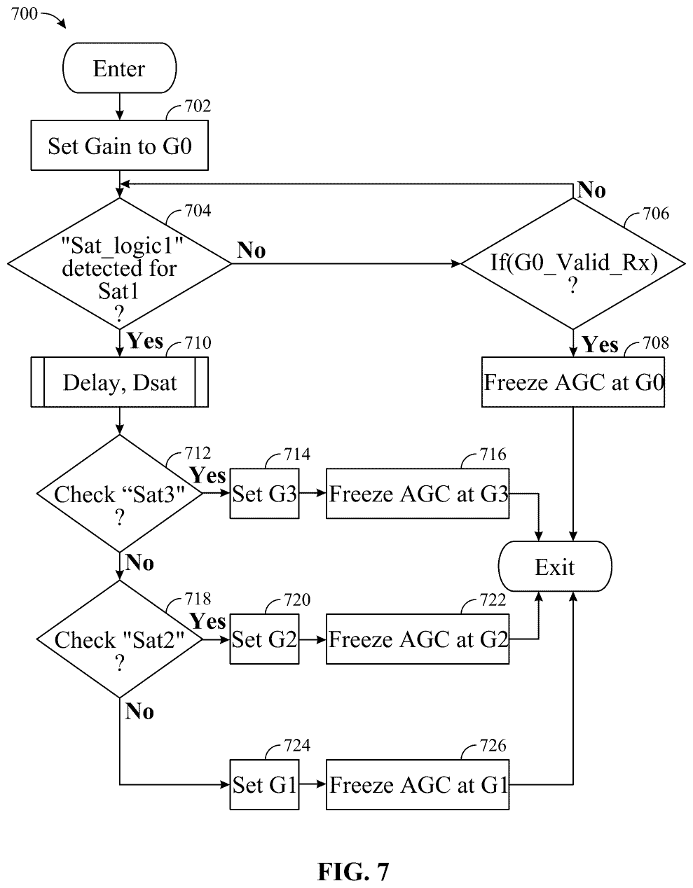

The AGC logic 410 is generally configured to control a gain state of the LNA 324 based on at least one of the logic signal 460, logic signal 462, or the logic signal 464. In certain aspects, the AGC logic 410 may select a gain state from a plurality of gain states, and generate a logic signal 466 to trigger a switch in the gain state of the LNA 324 to the selected gain state. Note, the AGC logic 410 may be included within the controller 336 and is described in greater detail below with respect to FIG. 7.

Note that FIG. 4 depicts an illustrative example of an apparatus for performing RxAGC for a wireless RX path 404, and that the apparatus for performing RxAGC may have different configurations consistent with the functionality described herein. For example, while FIG. 4 depicts the saturation detector circuit 420 being coupled to the second output (OUT_{A2}) of the PGA 342, in certain aspects, the saturation detector circuit 420 may be coupled to the first output (OUT_{A1}) of the PGA 342, the second output (OUT_{A2}) of the PGA 342, or any combination thereof. Similarly, while FIG. 4 depicts the saturation detector circuit 430 being coupled to the second output (OUT_{T2}) of the TIA 340, in certain aspects, the saturation detector circuit 430 may be coupled to the first output (OUT_{T1}) of the TIA 340, the second output (OUT_{T2}) of the TIA 340, or any combination thereof. Similarly, while FIG. 4 depicts the LNA 324 having a single-ended output, in certain aspects, the LNA 324 may have a dual-ended output. In such aspects, the saturation detector circuit 430 may be coupled to at least one output of the LNA 324.

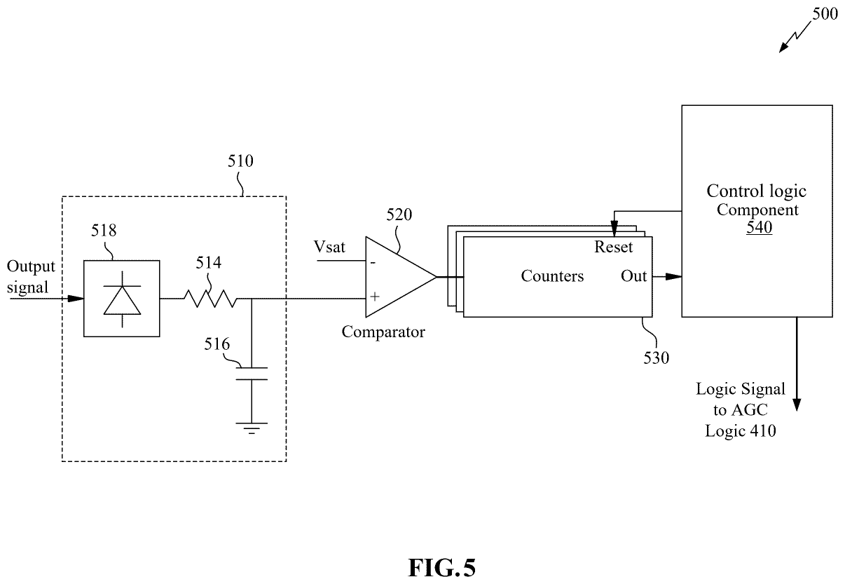

Each saturation detector circuit 420, 430, and 440 may be implemented with a respective power detector circuit, a respective comparator, one or more counters, and control logic. FIG. 5 illustrates an example saturation detector circuit 500, according to certain aspects of the present disclosure. The saturation detector circuit 500 may be an illustrative example implementation of the saturation detector circuit 420, saturation detector circuit 430, and/or the saturation detector circuit 440.

As shown, the saturation detector circuit 500 includes, without limitation, a power detector circuit 510, a comparator 520, one or more counters 530, and control logic 540. The power detector circuit 510 includes a diode 518, a resistor 514, and a capacitor 516. The power detector circuit 510 may be configured to determine a power level of the respective output signal within the RX path 404. For saturation detector circuit 440, the output signal may be an RF signal output from the LNA 324; for saturation detector circuit 430, the output signal may be a downconverted signal (e.g., baseband signal, intermediate frequency (IF) signal, etc.) output from the TIA 340; and for saturation detector circuit 420, the output signal may be an amplified downconverted signal output from the PGA 342. The power detector circuit 510 may be configured to provide an analog output or a digital output.

The comparator 520 has a first input coupled to an output of the power detector circuit 510 and has a second input coupled to a voltage source with an output voltage labeled “Vsat.” The comparator 604 is configured to compare the power level of the output signal to the threshold defined by the Vsat voltage, and to output a digital signal, based on the comparison. The threshold defined by Vsat may be set based on a respective threshold power level (e.g., RSSI) that each saturation detector circuit is configured to compare the output signal to. For example, for saturation detector circuit 420, the threshold defined by Vsat may correspond to a first threshold power level (e.g., −60 decibels per milliwatt (dBm) RX level at antenna); for saturation detector circuit 430, the threshold defined by Vsat may correspond to a second threshold power level (e.g., −44 dBm RX level at antenna); and for saturation detector circuit 440, the threshold defined by Vsat may correspond to a third threshold power level (e.g., −30 dBm RX level at antenna). In certain aspects, the third threshold level may be greater than the first threshold level and the second threshold level, and the second threshold level may be greater than the first threshold level.

Each counter 530 is generally configured to count a number of times that the power level of the output signal exceeds Vsat over a respective running time window. Each counter 530 may be clocked by a same clock signal. Each saturation detector circuit may be configured with a respective counter 530 for each time window over which the saturation detector circuit is configured to monitor for saturation of the receiver. For example, saturation detector circuit 420 may include two counters 530, each configured to monitor for saturation over a different time window (or a different time interval within a same running time window), saturation detector circuit 430 may include one counter 530 configured to monitor for saturation over a time window (or a single time interval within a running time window), and saturation detector circuit 440 may include one counter 530 configured to monitor for saturation over a time window (or a single time interval within a running time window).

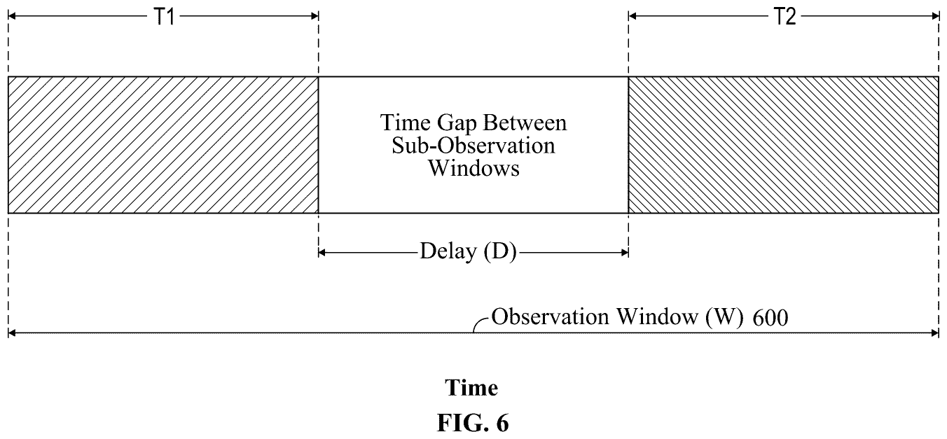

Consider FIG. 6 which depicts an example observation window 600, according to certain aspects of the present disclosure. The observation window 600 is an illustrative example of a running time window that may be used by the saturation detector circuit 500, which is an illustrative example of each of the saturation detector circuits 420, 430, and 440. The observation window 600 is a moving time window having a first time interval (T1) (or sub-observation window) and a second time interval (T2) (or sub-observation window). The first time interval (T1) may be separated in time from the second time interval (T2) by a predetermined amount of time (e.g., delay (D)). At least one of the first time interval (T1), second time interval (T2), or delay (D) may be configurable. The duration of the observation window 600 (as well as the time intervals thereof) may be based on the operating frequency. For example, at 38.4 MHz, the duration of the observation window 600 may be approximately 1.5 μs. In this example, assuming the first time interval (T1), the second time interval (T2), and the delay (D) are equal, the duration of each of the first time interval (T1), the second time interval (T2), and the delay (D) may be approximately 0.5 μs.

Referring back to FIG. 5, the saturation detector circuit 420 may include a first counter 530-1 configured to count a first number of times that a power of the output signal from the PGA 342 exceeded the respective Vsat for saturation detector circuit 420 during a first prior time window (e.g., [t_{current}:(t_{current}-T2)] of observation window 600), and include a second counter 530-2 configured to count a second number of times that the power of the output signal from the PGA 342 exceeded the respective Vsat for saturation detector circuit 420 during a second prior time window (e.g., [(t_{current}-T2-D):(t_{current}-T2-D-T1)] of observation window 600). Additionally, the saturation detector circuit 430 may include a counter 530 configured to count a number of times that a power of the output signal from the TIA 340 exceeded the respective Vsat for saturation detector circuit 430 during a prior time window (e.g., [t_{current}:(t_{current}-T2)] of observation window 600). Additionally, the saturation detector circuit 440 may include a counter 530 configured to count a number of times that a power of the output signal from the LNA 324 exceeded the respective Vsat for saturation detector circuit 440 during a prior time window (e.g., [t_{current}:(t_{current}-T2)] of observation window 600).

Continuing with FIG. 5, the control logic 540 has an input coupled to the output of the counter(s) 530, and has a first output configured to reset the counter(s) 530. The control logic 540 has a second output coupled to an input of AGC logic 410. In certain aspects, the control logic 540 may generate a logic signal (e.g., logic signal 460, logic signal 462, or logic signal 464) to indicate saturation within the receiver when the value(s) of the counter(s) 530 satisfy a respective criterion associated with the respective saturation detector circuit.

For example, for the saturation detector circuit 420, the criterion may include (i) the first number of times from counter 530-1 (of saturation detector circuit 420) being greater than or equal to a threshold “th_high_det_420” and (ii) the second number of times from counter 530-2 (of saturation detector circuit 420) being less than a threshold “th low_det 420.” For the saturation detector circuit 430, the criterion may include the number of times from counter 530 (of saturation detector circuit 430) being greater than or equal to a threshold “th_high_det_430.” For the saturation detector circuit 440, the criterion may include the number of times from counter 530 (of saturation detector circuit 440) being greater than or equal to a threshold “th_high_det 440.”

FIG. 7 is a flowchart of a method 700 for performing one-step “fast” RxAGC to control a gain state of an LNA (e.g., LNA 324) in a RX path (e.g., RX path 304, RX path 404, etc.), according to certain aspects of the present disclosure. The method 700 may be performed by the controller 336 or one or more components thereof, such as AGC logic 410, for example.

Method 700 may enter at block 702, where the controller sets the initial gain state to G0. At block 704, the controller determines whether a logic signal 460 indicating saturation within the receiver has been generated by the saturation detector circuit 420. If the logic signal 460 has not been generated, then the method 700 proceeds to block 706. If the logic signal 460 has been generated, then the method 700 proceeds to block 710.

At block 706, the controller determines if the current gain state G0 is a valid gain state. If so, then the method 700 proceeds to block 708. If not, then the method 700 proceeds to block 704. At block 708, the controller freezes the RxAGC at G0.

At block 710, the controller delays for a predetermined amount of time (e.g., approximately 0.7 μs or some other amount of time). At block 712, the controller determines whether a logic signal 464 indicating saturation within the receiver has been generated by the saturation detector circuit 440. If so, then the method 700 proceeds to block 714. If not, then the method 700 proceeds to block 718. At block 714, the controller selects the gain state G3 from multiple gain states. At block 716, the controller freezes the RxAGC at G3.

At block 718, the controller determines whether a logic signal 462 indicating saturation within the receiver has been generated by the saturation detector circuit 430. If so, then the method 700 proceeds to block 720. If not, then the method 700 proceeds to block 724.

At block 720, the controller selects the gain state G2 from multiple gain states. At block 722, the controller freezes the RxAGC at G2. At block 724, the controller selects the gain state G1 from multiple gain states. At block 726, the controller freezes the RxAGC at G1.

In certain aspects, assuming the RX input level of an input signal to the LNA 324 is −20 dBm, the RxAGC described herein may be able to achieve greater than 25 dB peak signal-to-noise ratio (SNR) with at least four gain sates. Note, however, that while FIG. 7 describes the RxAGC being performed with four gain states, in certain aspects, the RxAGC described herein may be performed with more than four gain states.

### Example Operations

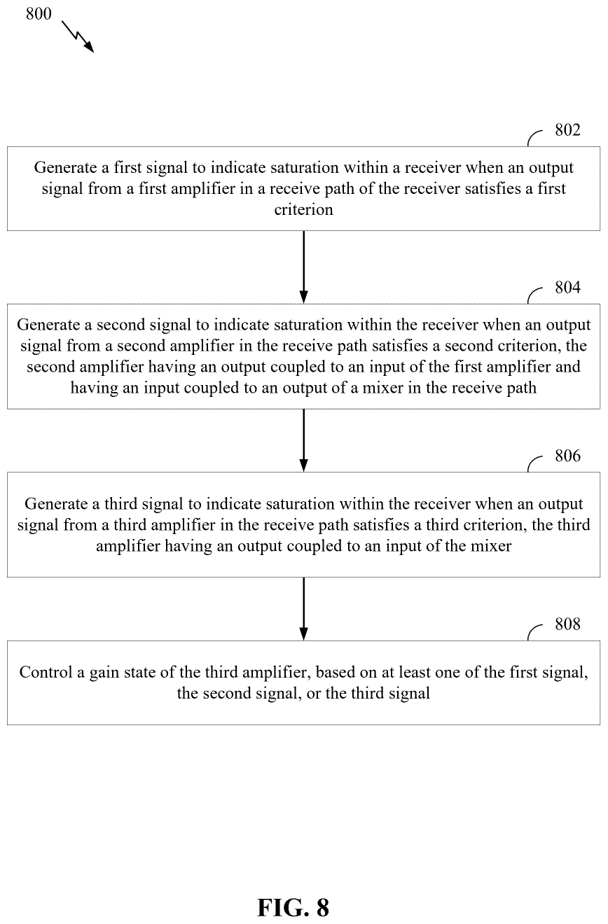

FIG. 8 is a flow diagram of example operations 800 for performing automatic gain control (AGC) for a RX path (e.g., RX path 304, RX path 404, etc.), in accordance with certain aspects of the present disclosure. The operations 800 may be performed, for example, by a controller (e.g., controller 336).

The operations 800 may generally involve, at block 802, generating a first signal (e.g., logic signal 460) to indicate saturation within a receiver when an output signal from a first amplifier (e.g., PGA 342) in a receive path (e.g., RX path 304 or RX path 404) of the receiver satisfies a first criterion.

The operations 800 may also involve, at block 804, generating a second signal (e.g., logic signal 462) to indicate saturation within the receiver when an output signal from a second amplifier (e.g., TIA 340) in the receive path satisfies a second criterion. The second amplifier has an output coupled to an input of the first amplifier and has an input coupled to an output of a mixer (e.g., mixer 326) in the receive path.

The operations 800 may also involve, at block 806, generating a third signal (e.g., logic signal 464) to indicate saturation within the receiver when an output signal from a third amplifier (e.g., LNA 324) in the receive path satisfies a third criterion. The third amplifier has an output coupled to an input of the mixer.

The operations 800 may further involve, at block 808, controlling a gain state of the third amplifier, based on at least one of the first signal, the second signal, or the third signal.

### Example Aspects

In addition to the various aspects described above, specific combinations of aspects are within the scope of the present disclosure, some of which are detailed below:
Aspect 1: An apparatus for wireless communications, the apparatus comprising: a receiver comprising: a receive path comprising a first amplifier, a second amplifier having an output coupled to an input of the first amplifier, a mixer having an output coupled to an input of the second amplifier, and a third amplifier having an output coupled to an input of the mixer; a first saturation detector circuit coupled to at least one output of the first amplifier and configured to generate a first signal to indicate saturation within the receiver when an output signal from the first amplifier satisfies a first criterion; a second saturation detector circuit coupled to at least one output of the second amplifier and configured to generate a second signal to indicate saturation within the receiver when an output signal from the second amplifier satisfies a second criterion; and a third saturation detector circuit coupled to at least one output of the third amplifier and configured to generate a third signal to indicate saturation within the receiver when an output signal from the third amplifier satisfies a third criterion; and control logic coupled to the receiver, the control logic being configured to control a gain state of the third amplifier, based on at least one of the first signal, the second signal, or the third signal.
Aspect 2: The apparatus of Aspect 1, wherein the first saturation detector circuit is further configured to: count a first number of times that a power of the output signal from the first amplifier exceeded a first threshold over a first past time window; and count a second number of times that the power of the output signal from the first amplifier exceeded the first threshold over a second past time window.
Aspect 3: The apparatus of Aspect 2, wherein the first criterion comprises (i) the first number of times being greater than or equal to a third threshold and (ii) the second number of times being less than a fourth threshold.
Aspect 4: The apparatus according to any of Aspects 2-3, wherein the second past time window is designated to occur prior to the first past time window.
Aspect 5: The apparatus according to any of Aspects 2-4, wherein a start of the first past time window is designated to occur after a predefined amount of time has elapsed after an end of the second past time window.
Aspect 6: The apparatus according to any of Aspects 1-5, wherein the second saturation detector circuit is further configured to count a number of times that a power of the output signal from the second amplifier exceeded a first threshold over a past time window.
Aspect 7: The apparatus of Aspect 6, wherein the second criterion comprises the number of times being greater than or equal to a second threshold.
Aspect 8: The apparatus according to any of Aspects 1-7, wherein the third saturation detector circuit is further configured to count a number of times that a power of the output signal from the third amplifier exceeded a first threshold over a past time window.
Aspect 9: The apparatus of Aspect 8, wherein the third criterion comprises the number of times being greater than or equal to a second threshold.
Aspect 10: The apparatus according to any of Aspects 1-9, wherein to control the gain state of the third amplifier, the control logic is configured to: set the gain state of the third amplifier to a first gain state of a plurality of gain states; determine a second gain state from the plurality of gain states, based on an indication of saturation from the first signal; and generate a logic signal to trigger a switch in the gain state of the third amplifier from the first gain state to the second gain state.
Aspect 11: The apparatus according to any of Aspects 1-10, wherein to control the gain state of the third amplifier, the control logic is configured to: set the gain state of the third amplifier to a first gain state of a plurality of gain states; determine a second gain state from the plurality of gain states, based on an indication of saturation from the first signal and an indication of saturation from the third signal; and generate a logic signal to trigger a switch in the gain state of the third amplifier from the first gain state to the second gain state.
Aspect 12: The apparatus according to any of Aspects 1-11, wherein to control the gain state of the third amplifier, the control logic is configured to: set the gain state of the third amplifier to a first gain state of a plurality of gain states; determine a second gain state from the plurality of gain states, based on an indication of saturation from the first signal, an indication of saturation from the third signal, and an indication of saturation from the second signal; and generate a logic signal to trigger a switch in the gain state of the third amplifier from the first gain state to the second gain state.
Aspect 13: The apparatus according to any of Aspects 1-12, wherein: the first amplifier comprises a baseband amplifier; the second amplifier comprises a transimpedance amplifier (TIA); and the third amplifier comprises a low noise amplifier (LNA).
Aspect 14: The apparatus according to any of Aspects 1-13, wherein the apparatus is an Internet of things (IoT) device.
Aspect 15: A wireless device comprising: an antenna; a receiver coupled to the antenna, the receiver comprising: a receive path comprising a first amplifier, a second amplifier having an output coupled to an input of the first amplifier, a mixer having an output coupled to an input of the second amplifier, and a third amplifier having an output coupled to an input of the mixer; a first saturation detector circuit coupled to at least one output of the first amplifier and configured to generate a first signal to indicate saturation within the receiver when an output signal from the first amplifier satisfies a first criterion; a second saturation detector circuit coupled to at least one output of the second amplifier and configured to generate a second signal to indicate saturation within the receiver when an output signal from the second amplifier satisfies a second criterion; and a third saturation detector circuit coupled to at least one output of the third amplifier and configured to generate a third signal to indicate saturation within the receiver when an output signal from the third amplifier satisfies a third criterion; and control logic coupled to the receiver, the control logic being configured to control a gain state of the third amplifier, based on at least one of the first signal, the second signal, or the third signal.
Aspect 16: The wireless device of Aspect 15, wherein: the first saturation detector circuit is further configured to (i) count a first number of times that a power of the output signal from the first amplifier exceeded a first threshold over a first past time window and (ii) count a second number of times that the power of the output signal from the first amplifier exceeded the first threshold over a second past time window; the second saturation detector circuit is further configured to count a number of times that a power of the output signal from the second amplifier exceeded a second threshold over a third past time window; and the third saturation detector circuit is further configured to count a number of times that a power of the output signal from the third amplifier exceeded a fourth threshold over a fourth past time window.
Aspect 17: The wireless device according to any of Aspects 15-16, wherein to control the gain state of the third amplifier, the control logic is configured to: set the gain state of the third amplifier to a first gain state of a plurality of gain states; determine a second gain state from the plurality of gain states, based on an indication of saturation from the first signal; and generate a logic signal to trigger a switch in the gain state of the third amplifier from the first gain state to the second gain state.
Aspect 18: The wireless device according to any of Aspects 15-17, wherein to control the gain state of the third amplifier, the control logic is configured to: set the gain state of the third amplifier to a first gain state of a plurality of gain states; determine a second gain state from the plurality of gain states, based on an indication of saturation from the first signal and an indication of saturation from the third signal; and generate a logic signal to trigger a switch in the gain state of the third amplifier from the first gain state to the second gain state.
Aspect 19: The wireless device according to any of Aspects 15-18, wherein to control the gain state of the third amplifier, the control logic is configured to: set the gain state of the third amplifier to a first gain state of a plurality of gain states; determine a second gain state from the plurality of gain states, based on an indication of saturation from the first signal, an indication of saturation from the third signal, and an indication of saturation from the second signal; and generate a logic signal to trigger a switch in the gain state of the third amplifier from the first gain state to the second gain state.
Aspect 20: A method for wireless communications, the method comprising: generating a first signal to indicate saturation within a receiver when an output signal from a first amplifier in a receive path of the receiver satisfies a first criterion; generating a second signal to indicate saturation within the receiver when an output signal from a second amplifier in the receive path satisfies a second criterion, the second amplifier having an output coupled to an input of the first amplifier and having an input coupled to an output of a mixer in the receive path; generating a third signal to indicate saturation within the receiver when an output signal from a third amplifier in the receive path satisfies a third criterion, the third amplifier having an output coupled to an input of the mixer; and controlling a gain state of the third amplifier, based on at least one of the first signal, the second signal, or the third signal.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components. For example, means for generating, means for determining a power level of an output signal, and/or means for counting may include a saturation detector circuit, such as the saturation detector circuit 420, 430, or 440 of FIG. 4 or the saturation detector circuit 500 of FIG. 5, or a controller (or processor), such as the controller 336 of FIG. 3. Means for controlling, means for determining, and/or means for setting may include a controller (or processor), such as the controller 336 of FIG. 3.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, “a processor,” “at least one processor,” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory,” or “one or more memories” generally refers to a single memory configured to store data and/or instructions or multiple memories configured to collectively store data and/or instructions.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An apparatus for wireless communications, the apparatus comprising:
a receiver comprising:
a receive path comprising a first amplifier, a second amplifier having an output coupled to an input of the first amplifier, a mixer having an output coupled to an input of the second amplifier, and a third amplifier having an output coupled to an input of the mixer;
a first saturation detector circuit coupled to at least one output of the first amplifier and configured to generate a first signal to indicate saturation within the receiver when an output signal from the first amplifier satisfies a first criterion;
a second saturation detector circuit coupled to at least one output of the second amplifier and configured to generate a second signal to indicate saturation within the receiver when an output signal from the second amplifier satisfies a second criterion; and
a third saturation detector circuit coupled to at least one output of the third amplifier and configured to generate a third signal to indicate saturation within the receiver when an output signal from the third amplifier satisfies a third criterion; and
control logic coupled to the receiver, the control logic being configured to control a gain state of the third amplifier, based on at least one of the first signal, the second signal, or the third signal.

2. The apparatus of claim 1, wherein the first saturation detector circuit is further configured to:
count a first number of times that a power of the output signal from the first amplifier exceeded a first threshold over a first past time window; and
count a second number of times that the power of the output signal from the first amplifier exceeded the first threshold over a second past time window.

3. The apparatus of claim 2, wherein the first criterion comprises (i) the first number of times being greater than or equal to a third threshold and (ii) the second number of times being less than a fourth threshold.

4. The apparatus of claim 2, wherein the second past time window is designated to occur prior to the first past time window.

5. The apparatus of claim 4, wherein a start of the first past time window is designated to occur after a predefined amount of time has elapsed after an end of the second past time window.

6. The apparatus of claim 1, wherein the second saturation detector circuit is further configured to count a number of times that a power of the output signal from the second amplifier exceeded a first threshold over a past time window.

7. The apparatus of claim 6, wherein the second criterion comprises the number of times being greater than or equal to a second threshold.

8. The apparatus of claim 1, wherein the third saturation detector circuit is further configured to count a number of times that a power of the output signal from the third amplifier exceeded a first threshold over a past time window.

9. The apparatus of claim 8, wherein the third criterion comprises the number of times being greater than or equal to a second threshold.

10. The apparatus of claim 1, wherein to control the gain state of the third amplifier, the control logic is configured to:
set the gain state of the third amplifier to a first gain state of a plurality of gain states;
determine a second gain state from the plurality of gain states, based on an indication of saturation from the first signal; and
generate a logic signal to trigger a switch in the gain state of the third amplifier from the first gain state to the second gain state.

11. The apparatus of claim 1, wherein to control the gain state of the third amplifier, the control logic is configured to:
set the gain state of the third amplifier to a first gain state of a plurality of gain states; determine a second gain state from the plurality of gain states, based on an indication of saturation from the first signal and an indication of saturation from the third signal; and
generate a logic signal to trigger a switch in the gain state of the third amplifier from the first gain state to the second gain state.

12. The apparatus of claim 1, wherein to control the gain state of the third amplifier, the control logic is configured to:
set the gain state of the third amplifier to a first gain state of a plurality of gain states;
determine a second gain state from the plurality of gain states, based on an indication of saturation from the first signal, an indication of saturation from the third signal, and an indication of saturation from the second signal; and
generate a logic signal to trigger a switch in the gain state of the third amplifier from the first gain state to the second gain state.

13. The apparatus of claim 1, wherein:
the first amplifier comprises a baseband amplifier;
the second amplifier comprises a transimpedance amplifier (TIA); and
the third amplifier comprises a low noise amplifier (LNA).

14. The apparatus of claim 1, wherein the apparatus is an Internet of things (IoT) device.

15. A wireless device comprising:
an antenna;
a receiver coupled to the antenna, the receiver comprising:
a receive path comprising a first amplifier, a second amplifier having an output coupled to an input of the first amplifier, a mixer having an output coupled to an input of the second amplifier, and a third amplifier having an output coupled to an input of the mixer;
a first saturation detector circuit coupled to at least one output of the first amplifier and configured to generate a first signal to indicate saturation within the receiver when an output signal from the first amplifier satisfies a first criterion;
a second saturation detector circuit coupled to at least one output of the second amplifier and configured to generate a second signal to indicate saturation within the receiver when an output signal from the second amplifier satisfies a second criterion; and
a third saturation detector circuit coupled to at least one output of the third amplifier and configured to generate a third signal to indicate saturation within the receiver when an output signal from the third amplifier satisfies a third criterion; and
control logic coupled to the receiver, the control logic being configured to control a gain state of the third amplifier, based on at least one of the first signal, the second signal, or the third signal.

16. The wireless device of claim 15, wherein:
the first saturation detector circuit is further configured to (i) count a first number of times that a power of the output signal from the first amplifier exceeded a first threshold over a first past time window and (ii) count a second number of times that the power of the output signal from the first amplifier exceeded the first threshold over a second past time window;
the second saturation detector circuit is further configured to count a number of times that a power of the output signal from the second amplifier exceeded a second threshold over a third past time window; and
the third saturation detector circuit is further configured to count a number of times that a power of the output signal from the third amplifier exceeded a fourth threshold over a fourth past time window.

17. The wireless device of claim 15, wherein to control the gain state of the third amplifier, the control logic is configured to:
set the gain state of the third amplifier to a first gain state of a plurality of gain states;
determine a second gain state from the plurality of gain states, based on an indication of saturation from the first signal; and
generate a logic signal to trigger a switch in the gain state of the third amplifier from the first gain state to the second gain state.

18. The wireless device of claim 15, wherein to control the gain state of the third amplifier, the control logic is configured to:
set the gain state of the third amplifier to a first gain state of a plurality of gain states;
determine a second gain state from the plurality of gain states, based on an indication of saturation from the first signal and an indication of saturation from the third signal; and
generate a logic signal to trigger a switch in the gain state of the third amplifier from the first gain state to the second gain state.

19. The wireless device of claim 15, wherein to control the gain state of the third amplifier, the control logic is configured to:
set the gain state of the third amplifier to a first gain state of a plurality of gain states;
determine a second gain state from the plurality of gain states, based on an indication of saturation from the first signal, an indication of saturation from the third signal, and an indication of saturation from the second signal; and
generate a logic signal to trigger a switch in the gain state of the third amplifier from the first gain state to the second gain state.

20. A method for wireless communications, the method comprising:
generating a first signal to indicate saturation within a receiver when an output signal from a first amplifier in a receive path of the receiver satisfies a first criterion;
generating a second signal to indicate saturation within the receiver when an output signal from a second amplifier in the receive path satisfies a second criterion, the second amplifier having an output coupled to an input of the first amplifier and having an input coupled to an output of a mixer in the receive path;
generating a third signal to indicate saturation within the receiver when an output signal from a third amplifier in the receive path satisfies a third criterion, the third amplifier having an output coupled to an input of the mixer; and
controlling a gain state of the third amplifier, based on at least one of the first signal, the second signal, or the third signal.
